(19) United States
(12) Patent Application Publication
(10) Pub. No.: US 2020/0091378 A1
(43) Pub. Date: Mar. 19, 2020

(54) DISPLAY PANEL AND DISPLAY APPARATUS

(71) Applicant: Shenzhen China Star Optoelectronics Semiconductor Display Technology Co., Ltd., Shenzhen, Guangdong (CN)

(72) Inventor: Yong FAN, Shenzhen, Guangdong (CN)

(21) Appl. No.: 16/301,870

(22) PCT Filed: Nov. 1, 2018
(86) PCT No.: PCT/CN2018/113272

§ 371 Date: Nov. 15, 2018

(30) Foreign Application Priority Data
Sep. 18, 2018 (CN) 201811085514.6

(51) Int. Cl. H01L 33/44; H01L 25/075

(52) U.S. Cl. CPC H01L 33/44; H01L 25/0753

(57) ABSTRACT

A display panel includes a substrate including a first surface and a second surface opposite to the first surface; an electrode layer is disposed on the first surface of the substrate; and a reflection functional layer is disposed on the electrode layer for reducing a reflectivity of the electrode layer.

### BACKGROUND OF INVENTION

### 1. Field of Invention

The present invention relates to a display filed, and particularly to a display panel and a display apparatus.

### 2. Related Art

Regarding traditional self-illumination devices, for example, such as organic light emitting diode display devices in mass production, due to metal electrodes have a high reflectivity, they can reflect light from an external light source. Furthermore, the light of the external light source reflected by the display devices significantly adversely affects display quality of the self-illumination devices. Generally, polarizers with ¼ wavelength phase are additionally added to the self-illumination devices to reduce the reflectivity of the metal electrodes, thereby to improve display quality of the self-illumination devices.

However, the polarizers have a high cost, and because the polarizers give rise to a decrease of 50-60% in luminous efficiency of the self-illumination devices, a light energy utilization rate is reduced.

### SUMMARY OF INVENTION

Accordingly, an object of the present invention is to provide a display panel and a display apparatus to mitigate effects caused by reflection of light from an external light source on metal electrodes of the display panel, and therefore to improve display quality.

To achieve the above-mentioned object, the display panel of the present invention a substrate comprises a first surface and a second surface opposite to the first surface;
an electrode layer disposed on the first surface of the substrate; and
a reflection functional layer disposed on the electrode layer for reducing a reflectivity of the electrode layer; the reflection functional layer comprising a first metal sublayer, a transparent non-metal sublayer laminated on the first metal sublayer, and a second metal sublayer laminated on the transparent non-metal sublayer;
wherein the first metal sublayer and the second metal sublayer each comprises at least one of molybdenum metal, chromium metal, and tungsten metal;
wherein the transparent non-metal sublayer comprises at least one of a nanometer indium tin oxide material, a transparent, electrically conductive oxide material, an indium gallium zinc oxide material, a silicon oxide material, and a silicon nitride material; and wherein a black light shading glue is disposed on the second surface of the substrate.

In the display panel of the present invention, the first metal sublayer has a thickness between 12 and 40 nanometers, the second metal sublayer has a thickness between 2 and 15 nanometers, and the transparent non-metal sublayer has a thickness between 3 and 7 nanometers.

In the display panel of the present invention, the display panel further comprises a light emitting layer and an encapsulation layer, the light emitting layer is disposed on the reflection functional layer, and the encapsulation layer is disposed on the light emitting layer and covering the reflection functional layer, and wherein a surface of the encapsulation layer is formed with a nano-imprinting microstructure.

In the display panel of the present invention, the nano-imprinting microstructure comprises a plurality of nanometer hemispheric protrusions spaced apart from each other and distributed in an array arrangement on the surface of the encapsulation layer.

In the display panel of the present invention, the light emitting layer comprises a plurality of micro light emitting diodes disposed in an array arrangement on the reflection functional layer.

In the display panel of the present invention, the electrode layer comprises a first sub-electrode layer and a second sub-electrode layer, the first sub-electrode layer comprising a source metal electrode, a drain metal electrode, and a common electrode spaced apart from each other, and the second sub-electrode layer comprising a gate metal electrode, and wherein the reflection functional layer covers the source metal electrode, the drain metal electrode, the common electrode, and the gate metal electrode.

In the display panel of the present invention, the reflection functional layer comprises a plurality of reflection blocks disposed corresponding to the source metal electrode, the drain metal electrode, the common electrode, and the gate metal electrode, respectively.

In the display panel of the present invention, projections of the plurality of the reflection blocks on the substrate are located at a non-light emitting area of the substrate.

The present invention further provides a display panel comprising a substrate comprising a first surface and a second surface opposite to the first surface; an electrode layer disposed on the first surface of the substrate; and a reflection functional layer disposed on the electrode layer for reducing a reflectivity of the electrode layer.

In the display panel of the present invention, the reflection functional layer comprises a first metal sublayer, a transparent non-metal sublayer laminated on the first metal sublayer, and a second metal sublayer laminated on the transparent non-metal sublayer, and wherein the first metal sublayer and the second metal sublayer each comprises at least one of molybdenum metal, chromium metal, and tungsten metal; the transparent non-metal sublayer comprises at least one of a nanometer indium tin oxide material, a transparent, electrically conductive oxide material, an indium gallium zinc oxide material, a silicon oxide material, and a silicon nitride material.

In the display panel of the present invention, the first metal sublayer has a thickness between 12 and 40 nanometers, the second metal sublayer has a thickness between 2 and 15 nanometers, and the transparent non-metal sublayer has a thickness between 3 and 7 nanometers.

In the display panel of the present invention, the display panel further comprises a light emitting layer and an encapsulation layer, the light emitting layer is disposed on the reflection functional layer, and the encapsulation layer is disposed on the light emitting layer and covering the reflection functional layer, and wherein a surface of the encapsulation layer is formed with a nano-imprinting microstructure.

In the display panel of the present invention, the nano-imprinting microstructure comprises a plurality of nanometer hemispheric protrusions spaced apart from each other and distributed in an array arrangement on the surface of the encapsulation layer.

In the display panel of the present invention, the light emitting layer comprises a plurality of micro light emitting diodes disposed in an array arrangement on the reflection functional layer.

In the display panel of the present invention, a black light shading glue is disposed on the second surface of the substrate.

In the display panel of the present invention, the electrode layer comprises a first sub-electrode layer and a second sub-electrode layer, the first sub-electrode layer comprising a source metal electrode, a drain metal electrode, and a common electrode spaced apart from each other, and the second sub-electrode layer comprising a gate metal electrode, and wherein the reflection functional layer covers the source metal electrode, the drain metal electrode, the common electrode, and the gate metal electrode.

In the display panel of the present invention, the reflection functional layer comprises a plurality of reflection blocks disposed corresponding to the source metal electrode, the drain metal electrode, the common electrode, and the gate metal electrode, respectively.

In the display panel of the present invention, projections of the plurality of the reflection blocks on the substrate are located on a non-light emitting area of the substrate.

The present invention further provides a display apparatus, comprising a display panel, the display panel comprising: a substrate comprising a first surface and a second surface opposite to the first surface; an electrode layer disposed on the first surface of the substrate; and a reflection functional layer disposed on the electrode layer for reducing a reflectivity of the electrode layer.

In the display panel of the present invention, the reflection functional layer comprises a first metal sublayer, a transparent non-metal sublayer laminated on the first metal sublayer, and a second metal sublayer laminated on the transparent non-metal sublayer, and wherein the first metal sublayer and the second metal sublayer each comprises at least one of molybdenum metal, chromium metal, and tungsten metal, and the transparent non-metal sublayer comprises at least one of a nanometer indium tin oxide material, a transparent conducting oxide material, an indium gallium zinc oxide material, a silicon oxide material, and a silicon nitride material.

Accordingly, the display panel of the present invention utilizes the reflection functional layer disposed on the electrode layer to reduce the reflectivity of the electrode layer. That is, when the light from the external light source impinges upon the display panel, the light passes though the reflection functional layer, and the adversely effects caused by reflection of light from an external light source on metal electrodes of the display panel are mitigated, thereby to improve display quality. Additionally, the display panel of the present invention is not necessary to utilize a polarizer to reduce the reflectivity of the metal electrodes, thereby to improve light energy utilization rate of the display panel.

### BRIEF DESCRIPTION OF DRAWINGS

FIG. 1 is a schematic structural view of a display panel of an embodiment of the present invention.

FIG. 2 is a schematic structural view of a reflection functional layer of the display panel of the embodiment of the present invention.

FIG. 3 is another schematic structural view of the display panel of an embodiment of the present invention.

FIG. 4 is still another schematic structural view of the display panel of an embodiment of the present invention.

### DESCRIPTION OF PREFERRED EMBODIMENTS

The following embodiments are referring to the accompanying drawings for exemplifying specific implementable embodiments of the present disclosure. In the description of the present invention, it is to be understood that the term “center”, “longitudinal”, “lateral”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise” and the like indicates orientation or the orientation or positional relationship based on the positional relationship shown in the drawings, for convenience of description only and the present invention is to simplify the description, but does not indicate or imply that the device or element referred to must have a particular orientation in a particular orientation construction and operation, and therefore not be construed as limiting the present invention. In addition, the terms “first”, “second” are used to indicate or imply relative importance or the number of technical features specified implicitly indicated the purpose of description and should not be understood. Thus, there is defined “first”, “second” features may explicitly or implicitly include one or more of the features. In the description of the new practice, the meaning of“plurality” is at least two, e.g. two, three, etc., unless explicitly specifically limited.

In the present invention, unless otherwise explicitly specified or limited, the terms “mounted,” “connected,” “connected,” “fixed” and like terms are to be broadly understood, for example, may be a fixed connection, may be is detachably connected to, or integrally; may be a mechanical connector, may be electrically connected; may be directly connected, can also be connected indirectly through intervening structures, it may be interaction between the two internal communicating elements or two elements. Those of ordinary skill in the art, to be understood that the specific meanings in the present invention in accordance with specific circumstances.

In the present invention, unless otherwise expressly specified or limited, the first feature in the “on” a second “lower” or the first and second features may include direct contact and may also include a first the second feature is not in direct contact, but the contact by the additional features therebetween. Also, the first feature a second feature in the “on”, “above”, “upper” and includes obliquely upward directly above first feature a second feature, or only represents a first characteristic level is higher than the height of the second feature. In the first feature a second feature “beneath”, “below” and “lower” feature includes a first and obliquely downward right below the second feature, or just less than the level represented by the first feature a second feature.

The following disclosure provides many different embodiments or examples to achieve different structures of the present invention. To simplify the disclosure of the present invention, be described hereinafter and the members of the specific examples provided. Of course, they are only illustrative, and are not intended to limit the present invention. Further, the present disclosure may repeat reference numerals in different embodiments and/or the reference letters. This repetition is for the purpose of simplicity and clarity, and does not indicate a relationship between the various embodiments and/or set in question. Further, the present invention provides various specific examples of materials and processes, but one of ordinary skill in the art may be appreciated that other processes and applications and/or other materials.

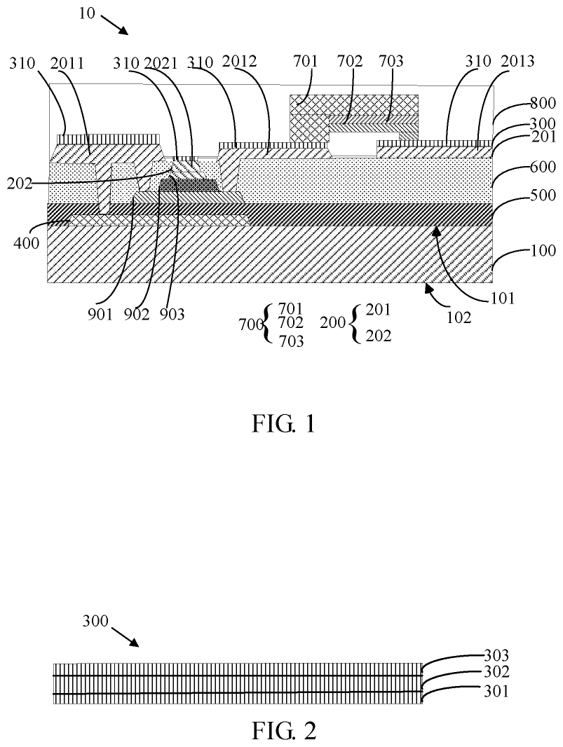

Please refer to FIG. 1. FIG. 1 is a schematic structural view of a display panel of an embodiment of the present invention. As sown in FIG. 1, a display panel 10 of the present invention includes a substrate 100, an electrode layer 200, and a reflection functional layer 300. The substrate 100 includes a first surface 101 and a second surface 102 opposite to the first surface 101. The electrode layer 200 is disposed on the first surface 101 of the substrate 100. The reflection functional layer 300 is disposed on the electrode layer 200.

The display panel 10 of the present invention utilizes the reflection functional layer 300 disposed on the electrode layer 200 to reduce a reflectivity of the electrode layer 200. Particularly, due to the electrode layer 200 has a high reflectivity, when light from an external light source impinges upon the display panel 10, the light from the external light source is being reflected off the electrode layer 200 to an outside.

In the embodiment of the present invention, when the light from the external light source impinges upon the display panel 10, the light is first reflected off the reflection functional layer 300 rather than to directly impinge upon the electrode layer 200, whereby the extent to which the light from the external light source reflected off the electrode layer 200 of the display panel 10 is reduced, and thus display quality of the display panel 10 is improved.

In one embodiment, please refer to FIG. 2 showing a schematic structural view of the reflection functional layer of the display panel of the embodiment of the present invention. Referring to FIG. 1 in combination with FIG. 2, the reflection functional layer 300 includes a first metal sublayer 301, a transparent non-metal sublayer 302 laminated on the first metal sublayer 301, and a second metal sublayer 303 laminated on the transparent non-metal sublayer 301. The first metal sublayer 301, the transparent non-metal sublayer 302, and the second metal sublayer 303 are laminated on the electrode layer 200 in sequence. Namely, when the light from the external light source impinges upon the display panel 10, the light passes though the first metal sublayer 301, the transparent non-metal sublayer 302, the second metal sublayer 303, and the electrode layer 200 in turn.

The first metal sublayer 301 and the second metal sublayer 303 each includes at least one of molybdenum metal, chromium metal, and tungsten metal. The transparent non-metal sublayer 302 includes at least one of a nanometer indium tin oxide material, a transparent, electrically conductive oxide material, an indium gallium zinc oxide material, a silicon oxide material, and a silicon nitride material.

The first metal sublayer 301 has a thickness between 12 and 40 nanometers, the second metal sublayer 303 has a thickness between 2 and 15 nanometers, and the transparent non-metal sublayer 302 has a thickness between 3 and 7 nanometers.

In one embodiment, the thickness of the second metal sublayer 303 is less than that of the first metal sublayer 301

In one embodiment, continuing referring to FIG. 1, the electrode layer 200 includes a first metal sublayer 201 and a second metal sublayer 202. The first metal sublayer 201 and the second metal sublayer 202 are disposed on different layers. Particularly, each of the first metal sublayer 201 and the second metal sublayer 202 is provided with the reflection functional layer 300 disposed thereon, wherein the first metal sublayer 201 is configured to form a source electrode and a drain electrode of a thin-film transistor, and a common electrode and the like. The second metal sublayer is configured to form a gate electrode of the thin-film transistor.

The first metal sublayer 201 includes a source metal electrode 2011 and a drain metal electrode 2012 spaced apart from each other, and a common electrode 2013. The second electrode layer 202 includes a gate electrode 2021. The reflection functional layer 300 covers the source metal electrode 2011, the drain metal electrode 2012, the common electrode 2013, and the gate metal electrode 2021.

The reflection functional layer 300 includes a plurality of reflection blocks 310 disposed corresponding to the source metal electrode 2011, the drain metal electrode 2012, the common electrode 2013, and the gate metal electrode 2021, respectively. For example, one of the plurality of reflection blocks 310 is disposed on the source metal electrode 2011, one of the plurality of reflection blocks 310 is disposed on the drain metal electrode 2012, one of the plurality of reflection blocks 310 is disposed on the common electrode 2013, and one of the plurality of reflection blocks 310 is disposed on the gate metal electrode, wherein each of the plurality of reflection blocks 310 is disposed corresponding to a respective electrode.

In one embodiment, each of the plurality of reflection blocks 310 has a size corresponding to a respective electrode. In another embodiment, each of the plurality of reflection blocks 310 covers a respective electrode. That is, each of the plurality of reflection blocks 310 can have a size greater than that of a respective electrode.

In one embodiment, projections of the plurality of the reflection blocks 310 on the substrate 100 are located at a non-light emitting area. In micro display panels, a light emitting area of the display panel takes up a smaller portion on the entire display panel, and the other portion of the display panel is a non-light emitting area. In order to reduce the reflectivity of an electrode layer at the non-light emitting area, the reflection functional layer 300 is capable of being disposed on the electrode layer corresponding to the non-light emitting area, thereby to maximally reduce the reflectivity of the electrode layer of the micro display panel, and to improve display quality.

The display panel 10 is exemplified by a micro light emitting diode (LED) display panel. Because a light emitting area of the micro LED display panel is in a small proportion to an area of the pixels and the remaining portion of the micro LED display panel is a non-light emitting area, to reduce the reflectivity of the non-light emitting area of the micro LED display panel is capable of maximally reducing the reflectivity of the micro LED display panel, thereby to improve display quality.

Please continue referring to FIG. 1. The display panel 10 includes the substrate 100, the electrode layer 200, the reflection functional layer 300, a light shading metal layer 400, a buffering layer 500, an intermediate dielectric layer 600, a light emitting layer 700, and an encapsulation layer 800.

The substrate 100 is exemplified by a transparent glass substrate or a sapphire substrate. The light shading metal layer 400 is disposed on the substrate 100.

The buffering layer 500 is disposed on the substrate 100 and covers the light shading metal layer 400. The buffering layer 500 is formed by deposition of silicon dioxide or silicon nitride. An electrically conductive groove layer 901 is further disposed on the buffering layer 500, an insulation layer 902 is disposed on the electrically conductive groove layer 901, and the second metal sublayer 202 is disposed on the insulation layer 902.

The intermediate dielectric layer 600 is formed by deposition of silicon dioxide or silicon nitride, and is deposited on the electrically conductive groove layer 901, the insulation layer 902, the second metal sublayer 202, and the buffering layer 500.

The light emitting layer 700 is disposed on the first metal sublayer 201. The light emitting layer 700 includes a cathode layer 701, an anode layer 703, and a light emitting material layer 702, wherein the light emitting layer 702 is disposed between the cathode layer 701 and the anode layer 703. Namely, the light emitting layer 700 includes a plurality of micro LEDs arranged in an array.

The encapsulation layer 800 is disposed on the light emitting layer 700 to protect the light emitting layer 700.

Furthermore, the display panel of the present invention utilizes the reflection functional layer 300 disposed on the electrode layer 200 to mitigate effects caused by reflection of light from an external light source on metal electrodes of the display panel. As a result, the display panel of the present invention is not required to be additionally provided with a polarizer to mitigate effects caused by reflection of light from an external light source on metal electrodes of the display panel, and thus a light energy utilization rate of the display panel is improved.

Accordingly, the display panel of the present invention utilizes the reflection functional layer disposed on the electrode layer to reduce the reflectivity of the electrode layer. That is, when the light from the external light source impinges upon the display panel, the light passes though the reflection functional layer, and the adversely effects caused by reflection of light from the external light source on metal electrodes of the display panel are mitigated, thereby to improve display quality. Additionally, the display panel of the present invention is not necessary to utilize a polarizer to reduce the reflectivity of the metal electrodes, thereby to improve light energy utilization rate of the display panel.

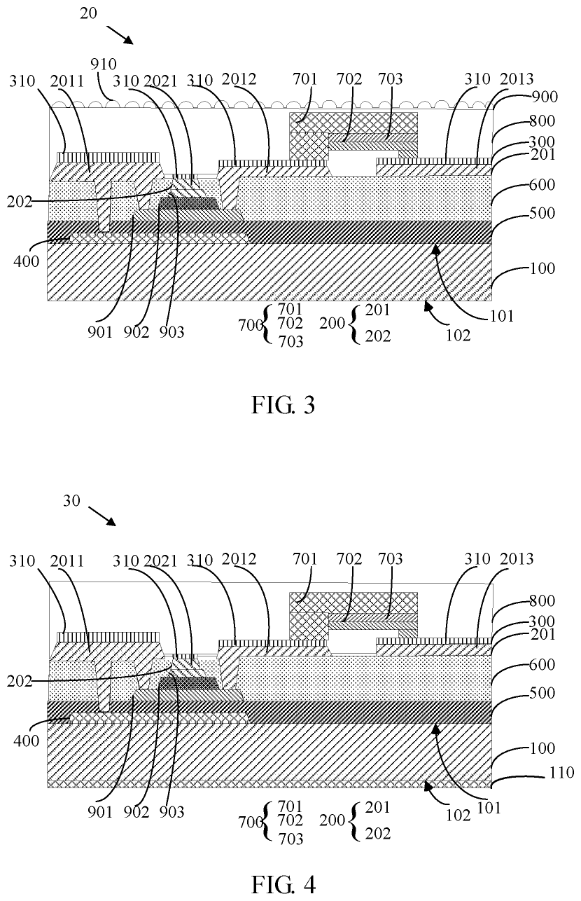

Please refer to FIG. 3. FIG. 3 is another schematic structural view of an embodiment of the present invention. Differences between a display panel as shown in FIG. 3 and the display panel as shown in FIG. 1 are as follows: a surface of the encapsulation layer 800 of a display panel 20 shown in FIG. 3 is formed with a nano-imprinting microstructure 900. The embodiment of the present invention utilizes the nano-imprinting microstructure 900 disposed on the surface of the encapsulation layer 800 to improve luminous efficiency of the display panel 20 and to restrain a mirror reflection image from being occurred.

The surface of the encapsulation layer 800 is formed with the nano-imprinting microstructure 900. The nano-imprinting microstructure 900 includes a plurality of nanometer hemispheric protrusions 910 spaced apart from each other and distributed in an array arrangement on an upper surface of the encapsulation layer 800.

Please refer to FIG. 4. FIG. 4 is another schematic structural view of an embodiment of the present invention. Differences between a display panel as shown in FIG. 4 and the display panel as shown in FIG. 1 are as follows: a black light shading glue 110 is disposed on the second surface 102 of the substrate 100 of a display panel 30 as shown in FIG. 4. The embodiment of the present invention utilizes the black light shading glue 110 disposed on the second surface 102 of the substrate 100 to improve luminous efficiency of the display panel 30 and to restrain a mirror reflection, image from being occurred. Specifically, the black light shading glue 110 covers the second surface 102 of the substrate 100.

The present invention further provides a display apparatus including the display panel as described in any one of the above-mentioned embodiments. Specific details can be referred to the description of the display panel of any one of the above-mentioned embodiments, and are not repeatedly depicted.

It is understood that the invention may be embodied in other forms within the scope of the claims. Thus the present examples and embodiments are to be considered in all respects as illustrative, and not restrictive, of the invention defined by the claims.

1. A display panel, comprising:
a substrate comprising a first surface and a second surface opposite to the first surface;
an electrode layer disposed on the first surface of the substrate; and
a reflection functional layer disposed on the electrode layer for reducing a reflectivity of the electrode layer; the reflection functional layer comprising a first metal sublayer, a transparent non-metal sublayer laminated on the first metal sublayer, and a second metal sublayer laminated on the transparent non-metal sublayer;
wherein the first metal sublayer and the second metal sublayer each comprises at least one of molybdenum metal, chromium metal, and tungsten metal;
wherein the transparent non-metal sublayer comprises at least one of a nanometer indium tin oxide material, a transparent, electrically conductive oxide material, an indium gallium zinc oxide material, a silicon oxide material, and a silicon nitride material; and
wherein a black shading glue is disposed on the second surface of the substrate.

2. The display panel of claim 1, wherein the first metal sublayer has a thickness between 12 and 40 nanometers, the second metal sublayer has a thickness between 2 and 15 nanometers, and the transparent non-metal sublayer has a thickness between 3 and 7 nanometers.

3. The display panel of claim 2, wherein the display panel further comprises a light emitting layer and an encapsulation layer, the light emitting layer is disposed on the reflection functional layer, and the encapsulation layer is disposed on the light emitting layer and covering the reflection functional layer, and wherein a surface of the encapsulation layer is formed with a nano-imprinting microstructure.

4. The display panel of claim 3, wherein the nano-imprinting microstructure comprises a plurality of nanometer hemispheric protrusions spaced apart from each other and distributed in an array arrangement on the surface of the encapsulation layer.

5. The display panel of claim 3, wherein the light emitting layer comprises a plurality of micro light emitting diodes disposed in an array arrangement on the reflection functional layer.

6. The display panel of claim 1, wherein the electrode layer comprises a first sub-electrode layer and a second sub-electrode layer, the first sub-electrode layer comprising a source metal electrode, a drain metal electrode, and a common electrode spaced apart from each other, and the second sub-electrode layer comprising a gate metal electrode, and wherein the reflection functional layer covers the source metal electrode, the drain metal electrode, the common electrode, and the gate metal electrode.

7. The display panel of claim 6, wherein the reflection functional layer comprises a plurality of reflection blocks disposed corresponding to the source metal electrode, the drain metal electrode, the common electrode, and the gate metal electrode, respectively.

8. The display panel of claim 7, wherein projections of the plurality of the reflection blocks on the substrate are located at a non-light emitting area of the substrate.

9. A display panel, comprising:
a substrate comprising a first surface and a second surface opposite to the first surface;
an electrode layer disposed on the first surface of the substrate; and
a reflection functional layer disposed on the electrode layer for reducing a reflectivity of the electrode layer.

10. The display panel of claim 9, wherein the reflection functional layer comprises a first metal sublayer, a transparent non-metal sublayer laminated on the first metal sublayer, and a second metal sublayer laminated on the transparent non-metal sublayer, and wherein the first metal sublayer and the second metal sublayer each comprises at least one of molybdenum metal, chromium metal, and tungsten metal; the transparent non-metal sublayer comprises at least one of a nanometer indium tin oxide material, a transparent, electrically conductive oxide material, an indium gallium zinc oxide material, a silicon oxide material, and a silicon nitride material.

11. The display panel of claim 10, wherein the first metal sublayer has a thickness between 12 and 40 nanometers, the second metal sublayer has a thickness between 2 and 15 nanometers, and the transparent non-metal sublayer has a thickness between 3 and 7 nanometers.

12. The display panel of claim 9, wherein the display panel further comprises a light emitting layer and an encapsulation layer, the light emitting layer is disposed on the reflection functional layer, and the encapsulation layer is disposed on the light emitting layer and covering the reflection functional layer, and wherein a surface of the encapsulation layer is formed with a nano-imprinting microstructure.

13. The display panel of claim 12, wherein the nano-imprinting microstructure comprises a plurality of nanometer hemispheric protrusions spaced apart from each other and distributed in an array arrangement on the surface of the encapsulation layer.

14. The display panel of claim 12, wherein the light emitting layer comprises a plurality of micro light emitting diodes disposed in an array arrangement on the reflection functional layer.

15. The display panel of claim 9, wherein a black shading glue is disposed on the second surface of the substrate.

16. The display panel of claim 9, wherein the electrode layer comprises a first sub-electrode layer and a second sub-electrode layer, the first sub-electrode layer comprising a source metal electrode, a drain metal electrode, and a common electrode spaced apart from each other, and the second sub-electrode layer comprising a gate metal electrode, and wherein the reflection functional layer covers the source metal electrode, the drain metal electrode, the common electrode, and the gate metal electrode.

17. The display panel of claim 16, wherein the reflection functional layer comprises a plurality of reflection blocks disposed corresponding to the source metal electrode, the drain metal electrode, the common electrode, and the gate metal electrode, respectively.

18. The display panel of claim 17, wherein projections of the plurality of the reflection blocks on the substrate are located on a non-light emitting area of the substrate.

19. A display apparatus, comprising a display panel, the display panel comprising:
a substrate comprising a first surface and a second surface opposite to the first surface;
an electrode layer disposed on the first surface of the substrate; and
a reflection functional layer disposed on the electrode layer for reducing a reflectivity of the electrode layer.

20. The display panel of claim 19, wherein the reflection functional layer comprises a first metal sublayer, a transparent non-metal sublayer laminated on the first metal sublayer, and a second metal sublayer laminated on the transparent non-metal sublayer; and wherein the first metal sublayer and the second metal sublayer each comprises at least one of molybdenum metal, chromium metal, and tungsten metal, and the transparent non-metal sublayer comprises at least one of a nanometer indium tin oxide material, a transparent conducting oxide material, an indium gallium zinc oxide material, a silicon oxide material, and a silicon nitride material.
